(19) United States
(12) Patent Application Publication
(10) Pub. No.: US 2018/0197894 A1
(43) Pub. Date: Jul. 12, 2018

(54) Pixel structure, manufacturing method and display panel

(71) Applicant: Shenzhen China Star Optoelectronics Technology Co. Ltd., Shenzhen, Guangdong (CN)

(72) Inventor: Wen SHI, Shenzhen, Guangdong (CN)

(73) Assignee: Shenzhen China Star Optoelectronics Technology Co. Ltd., Shenzhen, Guangdong (CN)

(21) Appl. No.: 15/123,666

(22) PCT Filed: Jul. 20, 2016
(86) PCT No.: PCT/CN2016/090582

§ 371 Date: Sep. 5, 2016

(30) Foreign Application Priority Data
Jun. 27, 2016 (CN) 201610485611.9

(51) Int. Cl. H01L 27/12; H01L 29/786; H01L 29/423; H01L 23/522; H01L 21/311

(52) U.S. Cl. CPC H01L 27/1248; H01L 29/78618; H01L 29/42384; H01L 27/156; H01L 27/1262; H01L 21/31111; H01L 23/5226

(57) ABSTRACT

A pixel structure, a manufacturing method and a display panel are provided. The pixel structure comprises a thin-film transistor array pattern unit and a pixel pattern unit which are disposed stacked; the pixel pattern unit includes a concave-convex structure film layer disposed on the thin-film transistor array pattern unit, a protection layer covered on the concave-convex structure film layer, a pixel electrode layer located on the protection layer, and electrically connected to the thin-film transistor array pattern unit and an emitting definition region so as to increase a light extraction rate of the light emitting device, decrease the power consumption of the display device and extend the life.

### BACKGROUND OF THE INVENTION

### 1. Field of the Invention

The present invention relates to a display technology field, and more particularly to a pixel structure, a manufacturing method and a display panel.

### 2. Description of Related Art

Currently, the importance of the display adopted for visible information transmission media is further strengthened. In order to dominate the future market, the display is developed toward a lighter, thinner, lower power, lower cost and better image quality trend. The organic electroluminescent diode (OLED) has advantages of self-luminous, fast response, wide viewing angle, high brightness, light and so on, the potential market prospect is optimistic by the industry. The quantum dot light emitting diode (QLED) has advantages of light color purity, high luminescence quantum efficiency, easy to adjust the light color and so on such that the QLED has become a powerful competitor of the OLED. The above two display technology is two main developing directions of current display field. However, because of the optical loss inside the structure of the device, only 20% of the emitted light of the device is used so as to greatly increase the power consumption of the display panel, and shorten the lift of the display device. The above situations have become an urgent problem required to be solved by the industry.

### SUMMARY OF THE INVENTION

The technology problem mainly solved by the present invention is to provide a pixel structure, manufacturing method and display panel in order to increase a light extraction rate of the light emitting device, decrease the power consumption of the display device and extending the life.

In order to solve the above technology problem, a technology solution adopted by the present invention is: a pixel structure, wherein, the pixel structure comprises a thin-film transistor array pattern unit and a pixel pattern unit which are stacked; the pixel pattern unit includes a concave-convex structure film layer disposed on the thin-film transistor array pattern unit, a protection layer covered on the concave-convex structure film layer, a pixel electrode layer located on the protection layer, and electrically connected to the thin-film transistor array pattern unit and an emitting definition region.

Wherein, the thin-film transistor array pattern unit includes a planarization layer for supporting the concave-convex structure film layer, a source pattern and a drain pattern disposed on the planarization layer and are separated, an active layer electrically connected between the source pattern and the drain pattern, a gate insulation layer covered on the active layer, and a gate pattern disposed between the gate insulation layer and a substrate.

Wherein, the pixel electrode layer is electrically connected to the drain pattern or the source pattern of the thin-film transistor array pattern unit through a connection hole passing through the protection layer, the concave-convex structure film layer and the planarization layer.

Wherein, the concave-convex structure film layer is formed through depositing a layer of a liquid prepolymer film on the planarization layer, and exposing the liquid prepolymer film, and the pixel electrode layer and the protection layer has a same concave-convex structure as the concave-convex structure film layer.

Wherein, a photoinitiator having a concentration in a range of 0.5%-2% is added into the liquid prepolymer film.

Wherein, a size of the concave-convex structure film layer is in a range of 500-5000 nanometers.

Wherein, the protection layer is an insulated inorganic nitride or oxide including one or a composite material of two above of silicon nitride, silicon oxide, aluminum nitride and aluminum oxide, and a thickness of the protection layer is in a range of 50-200 nanometers.

In order to solve the above technology problem, another technology solution adopted by the present invention is: a manufacturing method for a pixel structure, comprising: depositing a layer of a liquid prepolymer film on a planarization layer being manufactured with a thin-film transistor array pattern unit, and exposing the liquid prepolymer film in order to form a concave-convex structure film layer; covering with a protection layer on the concave-convex structure film layer; etching through the protection layer, the concave-convex structure film layer and the planarization layer of the thin-film transistor array pattern unit in order to form a via hole, and covering with a conductive material on the via hole in order to form a connection hole; disposing a pixel electrode layer on the protection layer such that the pixel electrode layer is electrically connected to a drain pattern or a source pattern of the thin-film transistor array pattern unit; and disposing an emitting definition region on the protection layer and at two sides of the pixel electrode layer, and making the emitting definition region to be electrically connected with the pixel electrode layer.

Wherein, a photoinitiator having a concentration in a range of 0.5%-2% is added into the liquid prepolymer film; a size of the concave-convex structure film layer is in a range of 500-5000 nanometers; and the protection layer is an insulated inorganic nitride or oxide including one or a composite material of two above of silicon nitride, silicon oxide, aluminum nitride and aluminum oxide, and a thickness of the protection layer is in a range of 50-200 nanometers.

In order to solve the above technology problem, another technology solution adopted by the present invention is: a display panel, wherein, the display panel comprises a pixel structure, and the pixel structure comprises a thin-film transistor array pattern unit and a pixel pattern unit which are stacked; the pixel pattern unit includes a concave-convex structure film layer disposed on the thin-film transistor array pattern unit, a protection layer covered on the concave-convex structure film layer, a pixel electrode layer located on the protection layer, and electrically connected to the thin-film transistor array pattern unit and an emitting definition region.

Wherein, the thin-film transistor array pattern unit includes a planarization layer for supporting the concave-convex structure film layer, a source pattern and a drain pattern disposed on the planarization layer and are separated, an active layer electrically connected between the source pattern and the drain pattern, a gate insulation layer covered on the active layer, and a gate pattern disposed between the gate insulation layer and a substrate.

Wherein, the pixel electrode layer is electrically connected to the drain pattern or the source pattern of the thin-film transistor array pattern unit through a connection hole passing through the protection layer, the concave-convex structure film layer and the planarization layer.

Wherein, the concave-convex structure film layer is formed through depositing a layer of a liquid prepolymer film on the planarization layer, and exposing the liquid prepolymer film, and the pixel electrode layer and the protection layer has a same concave-convex structure as the concave-convex structure film layer.

Wherein, a photoinitiator having a concentration in a range of 0.5%-2% is added into the liquid prepolymer film.

Wherein, a size of the concave-convex structure film layer is in a range of 500-5000 nanometers.

Wherein, the protection layer is an insulated inorganic nitride or oxide including one or a composite material of two above of silicon nitride, silicon oxide, aluminum nitride and aluminum oxide, and a thickness of the protection layer is in a range of 50-200 nanometers.

The beneficial effect of the present invention is: comparing to the conventional art, in the pixel structure of the present invention, through irradiating the liquid prepolymers such that the liquid prepolymers spontaneously form the concave-convex structure film layer. Then, manufacturing the protection layer and the pixel electrode layer having a same concave-convex structure as the concave-convex structure film layer in order to form a pixel structure in order to increase a light extraction rate of the light emitting device, decrease the power consumption of the display device and extend the life.

### BRIEF DESCRIPTION OF THE DRAWINGS

FIG. 1 is a schematic diagram of a pixel structure of the present invention;

FIG. 2 is the structure of the liquid prepolymers;

FIG. 3 is a flow chart of the manufacturing method for a pixel structure in FIG. 1;

FIG. 4a to FIG. 4f are process flow charts of the manufacturing method in FIG. 2; and

FIG. 5 is a structure schematic diagram of the display panel of the present invention.

### DETAILED DESCRIPTION OF THE PREFERRED EMBODIMENT

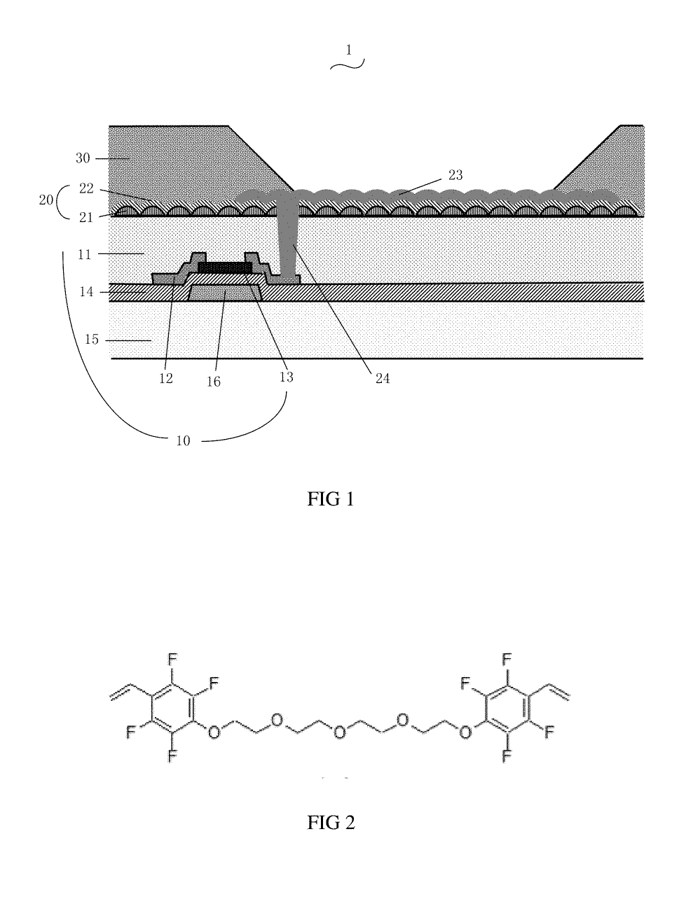

With reference to FIG. 1, and FIG. 1 is a schematic diagram of a pixel structure of the present invention. As shown in FIG. 1, the pixel structure 1 includes a thin-film transistor array pattern unit 10 and a pixel pattern unit 20 which are stacked. The pixel pattern unit 20 includes a concave-convex structure film layer 21 disposed on the thin-film transistor array pattern unit 10, a protection layer 22 covered on the concave-convex structure film layer 21, a pixel electrode layer 23 located on the protection layer 22, and electrically connected to the thin-film transistor array pattern unit 10 and an emitting definition region 30.

Wherein, the thin-film transistor array pattern unit 10 includes a planarization layer 11 for supporting the concave-convex structure film layer 21, a source pattern and a drain pattern 12 disposed on the planarization layer 11 and are separated, an active layer 13 electrically connected between the source pattern and the drain pattern 12, a gate insulation layer 14 covered on the active layer 13, and a gate pattern 16 disposed between the gate insulation layer 14 and a substrate 15.

Specifically, the pixel electrode layer 23 is electrically connected to the drain pattern or the source pattern 12 of the thin-film transistor array pattern unit 10 through a connection hole 24 passing through the protection layer 22, the concave-convex structure film layer 21 and the planarization layer 11. Wherein, the connection hole 24 is formed by a via hole 241 etching through the protection layer, the concave-convex structure film layer and the planarization layer 11 of the thin-film transistor array pattern unit 10 and a conductive material covered on the via hole. Wherein, the via hole 241 is disposed at an upper terminal of the drain pattern or the source pattern 12 of the thin-film transistor array pattern unit 10.

In the present embodiment, the concave-convex structure film layer 21 is formed by liquid prepolymers (the structure of the liquid prepolymers is shown as FIG. 2) after irradiating by an ultraviolet (UV) light to spontaneously gather. The size of the concave-convex structure film layer is adjusted through a thickness of the liquid prepolymers, and the size of the concave-convex structure film layer is in a range of 500-5000 nm. The protection layer 22 protects the concave-convex structure film layer 21 from being damaged in the subsequent manufacturing process. The protection layer 22 can be an insulated inorganic nitride or oxide including but not limited to silicon nitride, silicon oxide, aluminum nitride or aluminum oxide, and a thickness of the protection layer 22 is in a range of 50-200 nm. The pixel electrode layer 23 and the protection layer 22 have a same concave-convex structure as the concave-convex structure film layer 21 in order to increase a light extraction rate of the light emitting device, decrease the power consumption of the display device and extend the life.

Wherein, the process for forming the concave-convex structure film layer 21 includes two steps: the first step is forming a liquid prepolymer film; the second step is adopting an UV light to expose the liquid prepolymer film in order to spontaneously form a concave-convex structure. As shown in FIG. 1, the formation of the wavy concave-convex structure film layer 21 is that the material system maintains at a lowest energy state through the changing of the geometry. Preferably, in order to facilitate the formation process of the concave-convex structure film layer spontaneously formed by exposing through the UV light, a small amount of photoinitiator may be added into the liquid prepolymers, and the concentration of the photoinitiator is in a range of 0.5%-2%.

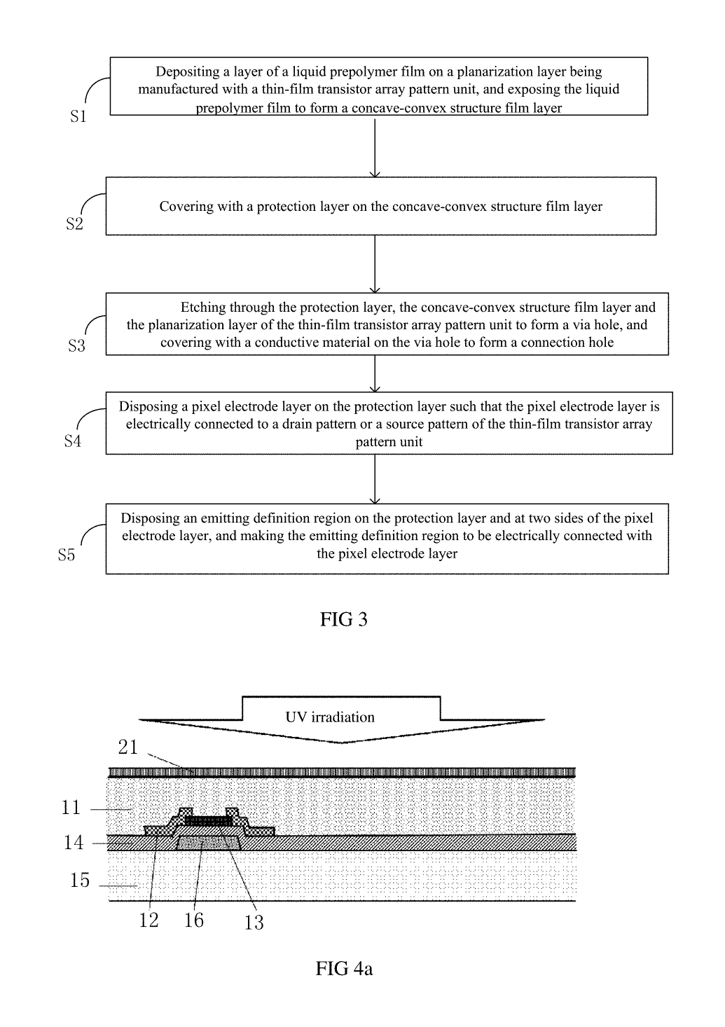

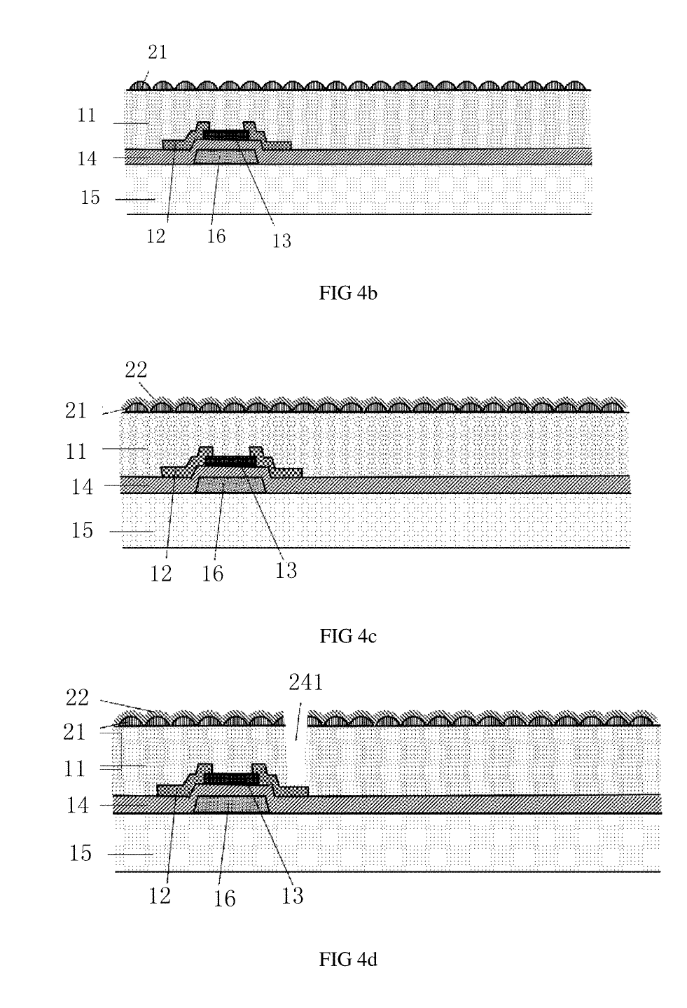

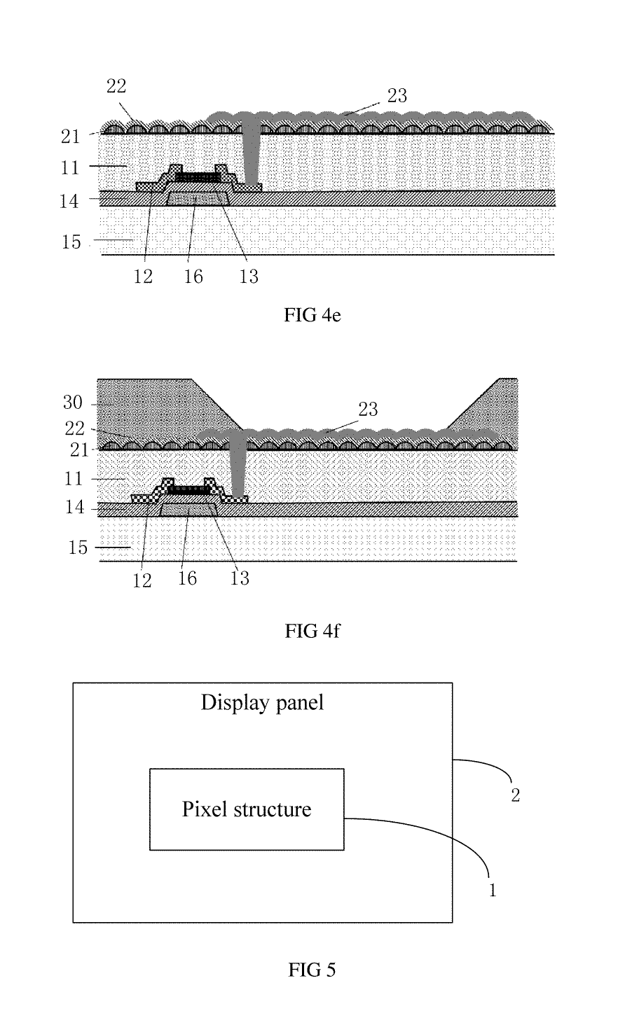

With reference to FIG. 3 and FIG. 4a to FIG. 4f, which are flow charts of the manufacturing method for a pixel structure of the present invention. The manufacturing method comprises:

Step S1: depositing a layer of a liquid prepolymer film on a planarization layer 11 being manufactured with a thin-film transistor array pattern unit 10, and placing the liquid prepolymer film under an UV light source. The liquid prepolymer film is spontaneously gathered because of the irradiation of the UV light in order to spontaneously form a concave-convex structure film layer 21. Wherein, the concave-convex structure film layer 21 is formed by liquid prepolymers (the structure of the liquid prepolymers is shown as FIG. 2) through the irradiation of the UV light to spontaneously gather. The size of a concave-convex structure of the concave-convex structure film layer 21 is adjusted through a thickness of the liquid prepolymer film, and the size of the concave-convex structure is in a range of 500-5000 nm.

Wherein, the process for forming the concave-convex structure film layer 21 includes two steps: the first step is forming a liquid prepolymer film; the second step is adopting an UV light to expose the liquid prepolymer film in order to spontaneously form a concave-convex structure. As shown in FIG. 1, the formation of the wavy concave-convex structure film layer 21 is that the material system maintains at a lowest energy state through the changing of the geometry. Preferably, in order to facilitate the formation process of the concave-convex structure film layer spontaneously formed by exposing through the UV light, a small amount of photoinitiator may be added into the liquid prepolymers, and the concentration of the photoinitiator is in a range of 0.5%-2%.

Step S2: covering with a protection layer 22 on the concave-convex structure film layer 21 such that the protection layer 22 has a same concave-convex structure as the concave-convex structure film layer 21 in order to prevent the concave-convex structure film layer 21 from being damaged in the subsequent process. Wherein, the protection layer 22 can be an insulated inorganic nitride or oxide including but not limited to silicon nitride, silicon oxide, aluminum nitride or aluminum oxide, and a thickness of the protection layer 22 is in a range of 50-200 nm

Step S3: etching through the protection layer 22, the concave-convex structure film layer 21 and the planarization layer 11 of the thin-film transistor array pattern unit 10 in order to form a via hole 241, and covering with a conductive material on the via hole 241 in order to form a connection hole 24. Wherein, the thin-film transistor array pattern unit 10 includes the planarization layer 11 for supporting the concave-convex structure film layer 21, a source pattern and a drain pattern 12 disposed on the planarization layer 11 and are separated, an active layer 13 electrically connected between the source pattern and the drain pattern 12, a gate insulation layer 14 covered on the active layer 13, and a gate pattern 16 disposed between the gate insulation layer 14 and a substrate 15.

Step S4: disposing a pixel electrode layer 23 on the protection layer 22 such that the pixel electrode layer 23 is electrically connected to the drain pattern or the source pattern 12 of the thin-film transistor array pattern unit 10 through the connection hole 24. Wherein, the pixel electrode layer 23 and the protection layer 22 have a same concave-convex structure as the concave-convex structure film layer 21 in order to increase a light extraction rate of the light emitting device, decrease the power consumption of the display device and extend the life.

Step S5: disposing an emitting definition region 30 on the protection layer 22 and at two sides of the pixel electrode layer 23, and making the emitting definition region 30 to be electrically connected with the pixel electrode layer 23. Wherein, the structure of the emitting definition region 30 is a conventional art, and the emitting definition region 30 can be disposed according to a requirement such as including an insulation layer, a metal conductive layer, etc. The structure of the emitting definition region 30 is not the protection scope of the present invention, no more describing in detail.

With reference to FIG. 5, which is a schematic diagram of a display panel of the present invention. As shown in FIG. 5, the display panel 2 includes a pixel structure 1 described above. The other elements and functions of the display panel 2 are the same as a conventional display panel, no more repeating.

In the pixel structure of the present invention, through irradiating the liquid prepolymers such that the liquid prepolymers spontaneously form the concave-convex structure film layer. Then, manufacturing the protection layer and the pixel electrode layer having a same concave-convex structure as the concave-convex structure film layer in order to form a pixel structure in order to increase a light extraction rate of the light emitting device, decrease the power consumption of the display device and extend the life.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A pixel structure, wherein, the pixel structure comprises a thin-film transistor array pattern unit and a pixel pattern unit which are stacked; the pixel pattern unit includes a concave-convex structure film layer disposed on the thin-film transistor array pattern unit, a protection layer covered on the concave-convex structure film layer, a pixel electrode layer located on the protection layer, and electrically connected to the thin-film transistor array pattern unit and an emitting definition region.

2. The pixel structure according to claim 1, wherein, the thin-film transistor array pattern unit includes a planarization layer for supporting the concave-convex structure film layer, a source pattern and a drain pattern disposed on the planarization layer and are separated, an active layer electrically connected between the source pattern and the drain pattern, a gate insulation layer covered on the active layer, and a gate pattern disposed between the gate insulation layer and a substrate.

3. The pixel structure according to claim 2, wherein, the pixel electrode layer is electrically connected to the drain pattern or the source pattern of the thin-film transistor array pattern unit through a connection hole passing through the protection layer, the concave-convex structure film layer and the planarization layer.

4. The pixel structure according to claim 1, wherein, the concave-convex structure film layer is formed through depositing a layer of a liquid prepolymer film on the planarization layer, and exposing the liquid prepolymer film, and the pixel electrode layer and the protection layer has a same concave-convex structure as the concave-convex structure film layer.

5. The pixel structure according to claim 4, wherein, a photoinitiator having a concentration in a range of 0.5%-2% is added into the liquid prepolymer film.

6. The pixel structure according to claim 1, wherein, a size of the concave-convex structure film layer is in a range of 500-5000 nanometers.

7. The pixel structure according to claim 1, wherein, the protection layer is an insulated inorganic nitride or oxide including one or a composite material of two above of silicon nitride, silicon oxide, aluminum nitride and aluminum oxide, and a thickness of the protection layer is in a range of 50-200 nanometers.

8. A manufacturing method for a pixel structure, comprising:
depositing a layer of a liquid prepolymer film on a planarization layer being manufactured with a thin-film transistor array pattern unit, and exposing the liquid prepolymer film in order to form a concave-convex structure film layer;
covering with a protection layer on the concave-convex structure film layer;
etching through the protection layer, the concave-convex structure film layer and the planarization layer of the thin-film transistor array pattern unit in order to form a via hole, and covering with a conductive material on the via hole in order to form a connection hole;
disposing a pixel electrode layer on the protection layer such that the pixel electrode layer is electrically connected to a drain pattern or a source pattern of the thin-film transistor array pattern unit; and
disposing an emitting definition region on the protection layer and at two sides of the pixel electrode layer, and making the emitting definition region to be electrically connected with the pixel electrode layer.

9. The manufacturing method according to claim 8, wherein, a photoinitiator having a concentration in a range of 0.5%-2% is added into the liquid prepolymer film; a size of the concave-convex structure film layer is in a range of 500-5000 nanometers; and the protection layer is an insulated inorganic nitride or oxide including one or a composite material of two above of silicon nitride, silicon oxide, aluminum nitride and aluminum oxide, and a thickness of the protection layer is in a range of 50-200 nanometers.

10. A display panel, wherein, the display panel comprises a pixel structure, and the pixel structure comprises a thin-film transistor array pattern unit and a pixel pattern unit which are stacked; the pixel pattern unit includes a concave-convex structure film layer disposed on the thin-film transistor array pattern unit, a protection layer covered on the concave-convex structure film layer, a pixel electrode layer located on the protection layer, and electrically connected to the thin-film transistor array pattern unit and an emitting definition region.

11. The display panel according to claim 10, wherein, the thin-film transistor array pattern unit includes a planarization layer for supporting the concave-convex structure film layer, a source pattern and a drain pattern disposed on the planarization layer and are separated, an active layer electrically connected between the source pattern and the drain pattern, a gate insulation layer covered on the active layer, and a gate pattern disposed between the gate insulation layer and a substrate.

12. The display panel according to claim 11, wherein, the pixel electrode layer is electrically connected to the drain pattern or the source pattern of the thin-film transistor array pattern unit through a connection hole passing through the protection layer, the concave-convex structure film layer and the planarization layer.

13. The display panel according to claim 10, wherein, the concave-convex structure film layer is formed through depositing a layer of a liquid prepolymer film on the planarization layer, and exposing the liquid prepolymer film, and the pixel electrode layer and the protection layer has a same concave-convex structure as the concave-convex structure film layer.

14. The display panel according to claim 13, wherein, a photoinitiator having a concentration in a range of 0.5%-2% is added into the liquid prepolymer film.

15. The display panel according to claim 10, wherein, a size of the concave-convex structure film layer is in a range of 500-5000 nanometers.

16. The display panel according to claim 10, wherein, the protection layer is an insulated inorganic nitride or oxide including one or a composite material of two above of silicon nitride, silicon oxide, aluminum nitride and aluminum oxide, and a thickness of the protection layer is in a range of 50-200 nanometers.
